(19) United States
(12) Patent Application Publication
(10) Pub. No.: US 2021/0074547 A1
(43) Pub. Date: Mar. 11, 2021

(54) METHOD FOR FABRICATING TRANSISTOR GATE, AS WELL AS TRANSISTOR STRUCTURE

(71) Applicant: Changxin Memory Technologies, Inc., Hefei (CN)

(72) Inventor: Bukang ZHOU, Hefei (CN)

(21) Appl. No.: 17/100,715

(22) Filed: Nov. 20, 2020

Related U.S. Application Data
(63) Continuation of application No. PCT/CN2019/093319, filed on Jun. 27, 2019.

(30) Foreign Application Priority Data
Jun. 28, 2018 (CN) 201810686974.8

(51) Int. Cl. H01L 21/28; H01L 29/49

(52) U.S. Cl. CPC H01L 21/28035; H01L 29/4925; H01L 21/28088

(57) ABSTRACT

A method for fabricating a transistor gate and a transistor structure thereof are disclosed herein. The method comprises: providing a substrate having a source region and a drain region; forming a gate oxide layer, a first polysilicon layer, a first isolation oxide layer, and a second polysilicon layer; doping the first polysilicon layer and second polysilicon layer to form a pre-gate structure; performing a annealing process so that the doped first polysilicon layer and second polysilicon layer are simultaneously and separately recrystallized to a first conductive silicon layer and a second conductive silicon layer, and electrically connecting the first conductive polysilicon layer and the second conductive polysilicon layer to each other; successively forming a conductive layer and a dielectric layer; forming a protective layer on a portion of the dielectric layer; etching from the dielectric layer until the gate oxide layer is exposed; and removing the protective layer to form the transistor gate.

### CROSS-REFERENCE TO RELATED APPLICATIONS

This application is a continuation application of International Patent Application No. PCT/CN2019/093319, filed on Jun. 27, 2019, which is based on and claims priority to and benefits of Chinese Patent Application No. 201810686974.8 and Chinese Patent Application No. 201821030367.8, both filed with the State Intellectual Property Office (SIPO) of the People's Republic of China on Jun. 28, 2018. The entire contents of the above-identified applications are incorporated herein by reference.

### TECHNICAL FIELD

The present invention relates to the field of semiconductor integrated circuit (IC) manufacturing technology and, in particular, to a method for fabricating a transistor gate and a transistor structure thereof.

### BACKGROUND

In the field of semiconductor integrated circuits (IC) manufacturing technology, the gate of a metal-oxide-semiconductor (MOS) field-effect transistor (FET) that is formed by deposition and subsequent high-temperature annealing often contains large-grain sized n-type silicon polycrystals, resulting in rough surfaces. In particular, the rough side surfaces of the gate can cause difficulty in controlling the effective gate length, since any tiny change in the effective gate length can exert a direct impact on the MOSFET's performance.

Therefore, reducing the grain size of n-type silicon crystals in MOSFET gates remains an urgent technical issue to be solved by those skilled in the art.

The information in this Background section is provided only for the purpose of having a better understanding of the background of the present invention, and does not necessarily constitute prior art already known to a person of ordinary skill in the art.

### SUMMARY

Embodiments of the present invention provide a method for fabricating a transistor gate and a transistor structure thereof for solving the current technical problem mentioned in the Background section.

In one aspect, an embodiment of the present invention provides a method for fabricating a transistor gate. The method comprising:

providing a substrate having a source region and a drain region spaced apart from each other;

forming a gate oxide layer on a top surface of the substrate, the gate oxide layer having a thickness that is greater than or equal to 2 nanometer (nm) and less than or equal to 5 nm;

forming a first polysilicon layer on a top surface of the gate oxide layer;

forming a first isolation oxide layer on a top surface of the first polysilicon layer, the first isolation oxide layer having a thickness that is greater than 0.1 nm and less than 1 nm;

forming a second polysilicon layer on a top surface of the first isolation oxide layer, the first isolation oxide layer separating the first polysilicon layer from the second polysilicon layer;

doping the first polysilicon layer and second polysilicon layer, wherein the doped first polysilicon layer, the first isolation oxide layer, and the doped second polysilicon layer together form a pre-gate structure;

annealing the pre-gate structure, wherein the doped first polysilicon layer and second polysilicon layer which are separated from each other by the first isolation oxide layer are simultaneously recrystallized into a first conductive silicon layer and a second conductive silicon layer, respectively, and that the thickness of the first isolation oxide layer is reduced until an electric connection established between the first conductive silicon layer and the second conductive silicon layer;

forming a conductive layer on a top surface of the annealed pre-gate structure, and forming a dielectric layer on a top surface of the conductive layer;

forming a patterned protective layer on a top surface of the dielectric layer, the patterned protective layer covering a portion of the dielectric layer aligned with a region between the source region and the drain region; and

etching from the dielectric layer to expose the gate oxide layer using the patterned protective layer as a mask, and removing the patterned protective layer by etching to form the transistor gate with the gate oxide layer covering the source region and the drain region.

In another aspect, an embodiment of the present invention provides a transistor structure. The transistor structure comprising:

a substrate having a source region and a drain region spaced apart from each other;

a gate oxide covering a portion of a top surface of the source region, a portion of a top surface of the drain region, and an exposed portion of a top surface of the substrate between the source region and the drain region, the gate oxide having a thickness that is greater than or equal to 2 nm and less than or equal to 5 nm; and

a transistor gate on the gate oxide and aligned with the exposed portion of the top surface of the substrate between the source region and the drain region, the transistor gate comprising a polycrystalline conductive structure adhering to the gate oxide, a metal conductive layer on the polycrystalline conductive structure, and a dielectric protective layer covering the metal conductive layer,

wherein the polycrystalline conductive structure comprises: a first gate conductive silicon layer on the gate oxide between the source region and the drain region, a second gate conductive silicon layer above the first gate conductive silicon layer, the second gate conductive silicon layer electrically connected to the first gate conductive silicon layer, wherein the transistor structure is prepared by annealing a doped first polysilicon layer and a doped second polysilicon layer so that the doped first polysilicon layer and the doped second polysilicon layer, while being separated from each other by a first gate isolation oxide layer, are simultaneously and separately recrystallized to the first gate conductive silicon layer and a second gate conductive silicon layer, respectively, and the thickness of the first gate isolation oxide layer is reduced until an electric connection established between the first gate conductive silicon layer and the second gate conductive silicon layer, and wherein the first gate isolation oxide layer comprises a thickness that is greater than 0.1 nm and less than 1 nm prior to the process of annealing.

The method and the transistor structure disclosed in the embodiments of the present invention offer the following advantages: the first and second polysilicon layers are formed and separated by the first isolation oxide layer; the first and second polysilicon layers are then doped to make them conductive layers; the doped first polysilicon layer, the first isolation oxide layer, and the doped second polysilicon layer together form a pre-gate structure; the pre-gate structure is then thermally annealed so that the doped first and second polysilicon layers, while being are separated by the first isolation oxide layer, are simultaneously and separately recrystallized into the first and second conductive silicon layers, respectively; the first isolation oxide layer is thinned until an electric connection is established between the first and second conductive silicon layers; the conductive and dielectric layers are successively formed on the top surface of the thermally annealed pre-gate structure; a patterned protective layer is formed on the top surface of the dielectric layer to cover the portion of the dielectric aligned with the region between the source region and the drain region; the patterned protective layer is used as a mask for an etching process that is performed from the dielectric layer until the gate oxide layer is exposed, and subsequently, the protective layer is removed by etching to form the transistor gate, and the gate oxide layer still covers the source region and the drain region. The obtained first and second conductive silicon layers contain small-grain sized crystals, resulting in more accurate MOSFET effective gate length and enhanced device performance including reliability and consistency.

The summary above is provided for illustrating, but not for limiting, the embodiments of the present invention. In addition to the above illustrative aspects, embodiments, and features, other aspects may be apparent from the following detailed description with respect to the accompanying drawings.

### BRIEF DESCRIPTION OF THE DRAWINGS

The following accompanying drawings may not be drawn to scale, and same or similar reference numerals may indicate the same or analogous components or elements, unless otherwise defined. It is to be understood that these drawings depict only some of the embodiments of the present invention and should not be considered as limitations of the scope thereof.

FIG. 1 is a flowchart of a method for fabricating a transistor gate in accordance with an embodiment of the present invention.

FIG. 2 is a schematic of a structure at step S100 in the method of FIG. 1.

FIG. 3 is a schematic of a structure at step S200 in the method of FIG. 1.

FIG. 4 is a schematic of a structure at step S310 in the method of FIG. 1.

FIG. 5 is a schematic of a structure at step S410 in the method of FIG. 1.

FIG. 6 is a schematic of a structure at step S320 in the method of FIG. 1.

FIG. 7 is a schematic of a structure at step S500 in the method of FIG. 1.

FIG. 8 is a schematic of a structure at step S600 in the method of FIG. 1.

FIG. 9 is a schematic of a structure at step S700 in the method of FIG. 1.

FIG. 10 is a schematic of a structure at step S800 in the method of FIG. 1.

FIG. 11 is a schematic of a structure at step S900 in the method of FIG. 1.

FIG. 12 is a schematic of a cross-section at a plane C-C of the transistor gate in FIG. 11.

FIG. 13 is a schematic of a structure having a third polysilicon fabricated in a method in accordance with another embodiment of the present invention.

FIG. 14 is a schematic of a structure having a high-temperature annealing in the method of FIG. 13.

FIG. 15 is a schematic of a transistor gate in the method of FIG. 14.

FIG. 16 is a schematic of a structure having a fourth polysilicon layer fabricated in a method in accordance with another embodiment of the present invention.

FIG. 17 is a schematic of a structure having a high-temperature annealing in the method of FIG. 16.

FIG. 18 is a schematic of the transistor gate in the method of FIG. 17.

FIG. 19 is a schematic of a transistor structure having the transistor gate of FIG. 11 in accordance with an embodiment of the present invention.

### LIST OF REFERENCE NUMERALS IN DRAWINGS

100 Substrate

110 Source Region

120 Drain Region

200 Gate Oxide Layer

210 Gate Oxide

310 First Polysilicon Layer

320 Second Polysilicon Layer

330 Third Polysilicon Layer

340 Fourth Polysilicon Layer

310a Doped First Polysilicon Layer

320a Doped Second Polysilicon Layer

311 First Conductive Silicon Layer

321 Second Conductive Silicon Layer

331 Third Conductive Silicon Layer

341 Fourth Conductive Silicon Layer

311a First Gate Conductive Silicon Layer

321a Second Gate Conductive Silicon Layer

331a Third Gate Conductive Silicon Layer

341a Fourth Gate Conductive Silicon Layer

410 First Isolation Oxide Layer

420 Second Isolation Oxide Layer

430 Third Isolation Oxide Layer

411 First Gate Isolation Oxide Layer

421 Second Gate Isolation Oxide Layer

431 Third Gate Isolation Oxide Layer

500 Conductive Layer

510 Metal Conductive Layer

600 Dielectric Layer

610 Dielectric Protective Layer

700 Protective Layer

800 Transistor Gate

810 Polycrystalline Conductive Structure

900 Lateral Spacer

910 First Spacer Layer

920 Second Spacer Layer

930 Third Spacer Layer

### DETAIL DESCRIPTION OF THE EMBODIMENTS

Below are descriptions merely for certain exemplary embodiments of the present invention. To those skilled in the art, the embodiments of the present invention disclosed herein may be modified in various manners without departing from the principal or scope of the invention. Accordingly, the accompanying drawings and description thereof are intrinsically exemplary rather than restrictive.

### Embodiment 1

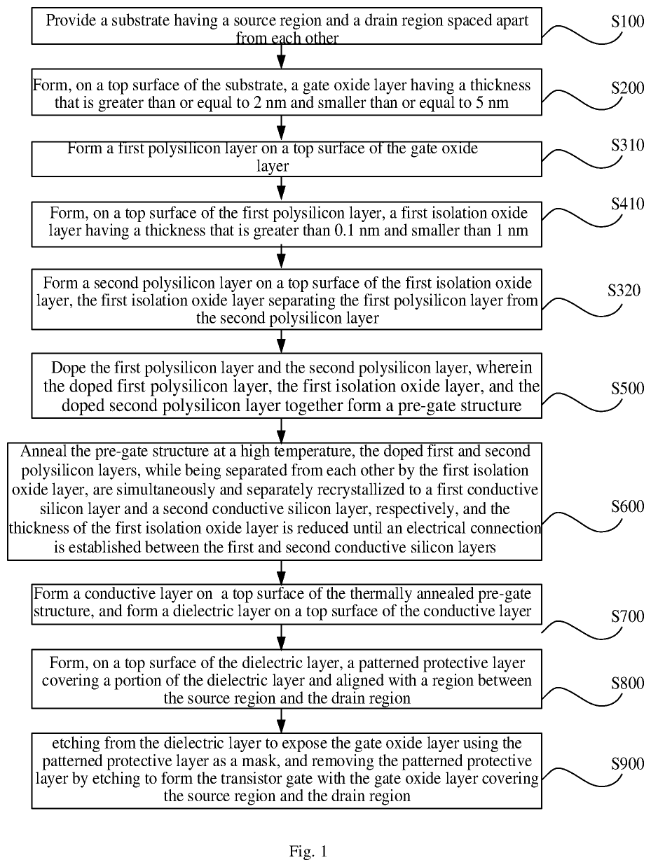

In the first embodiment of the present invention, as shown in FIG. 1, a method for fabricating a transistor gate is provided. The method includes steps for fabricating different layers of the transistor gate and the transistor structure thereof.

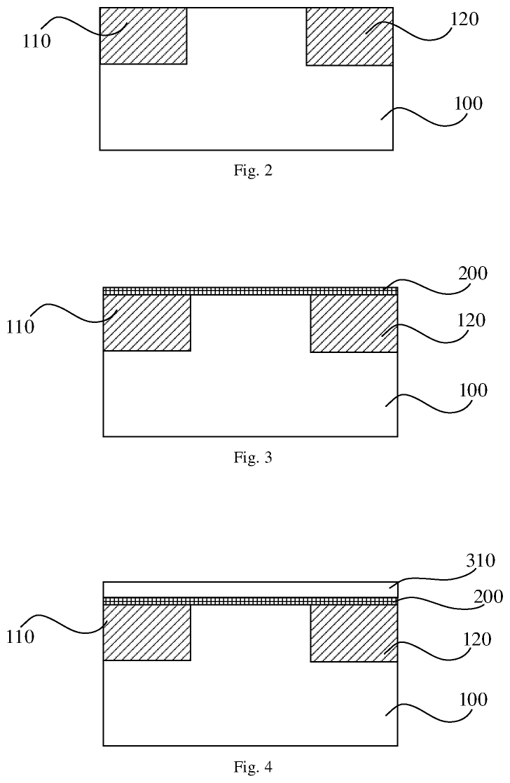

As shown in FIG. 2, in step S100, a source region 110 and a drain region 120 are formed in a substrate 100, wherein the source region 110 is spaced apart from the drain region 120.

As shown in FIG. 3, in step S200, a gate oxide layer 200 is formed on a top surface of the substrate 100 to cover a top surface of the source region 110, a top surface of the drain region 120, and the remaining exposed top surface of the substrate 100. The gate oxide layer 200 has a thickness that is greater than or equal to 2 nm and less than or equal to 5 nm.

As shown in FIG. 4, in step S310, a first polysilicon layer 310 is formed on a top surface of the gate oxide layer 200.

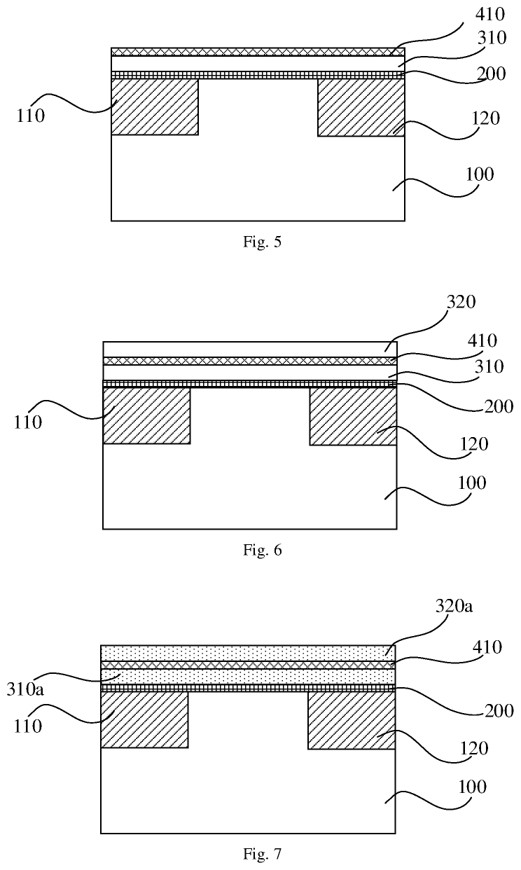

As shown in FIG. 5, in step S410, a first isolation oxide layer 410 is formed on a top surface of the first polysilicon layer 310. The first isolation oxide layer 410 has a thickness that is greater than 0.01 nm and less than 1 nm, and preferably greater than 0.1 nm and less than 1 nm.

As shown in FIG. 6, in step S320, a second polysilicon layer 320 is formed on a top surface of the first isolation oxide layer 410. The first isolation oxide layer 410 is formed to separate the first polysilicon layer 310 and the second polysilicon layer 320.

As shown in FIG. 7, in step S500, the first polysilicon layer 310 and the second polysilicon layer 320 are doped. The doped first polysilicon layer 310a, the first isolation oxide layer 410, and the doped second polysilicon layer 320a together form a pre-gate structure.

In step S500, the first polysilicon layer 310 and second polysilicon layer 320 may be doped with various elements, such as phosphorus, so that the non-conductive first polysilicon layer 310 and second polysilicon layer 320 may be transformed to conductive layers, such as the phosphorus-doped conductive first polysilicon layer and second polysilicon layer. The doped first polysilicon layer 310a, the first isolation oxide layer 410, and the doped second polysilicon layer 320a together form the pre-gate structure.

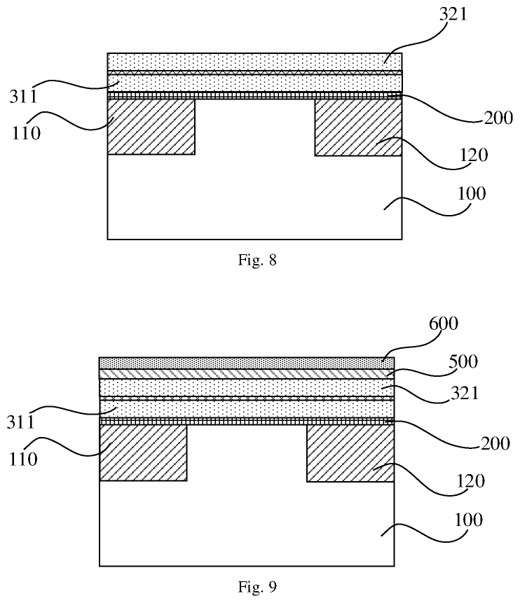

As shown in FIG. 8, in step S600, the pre-gate structure is annealed at a high temperature. Separated by the first isolation oxide layer 410, the doped first polysilicon layer 310a and the doped second polysilicon layer 320a are simultaneously and separately recrystallized into a first conductive silicon layer 311 and a second conductive silicon layer 321, respectively. The thickness of the first isolation oxide layer 410 is reduced until an electric connection is established between the first conductive silicon layers 311 and second conductive silicon layer 321.

As shown in FIG. 9, in step S700, a conductive layer 500 and a dielectric layer 600 are successively formed on a top surface of the thermally annealed pre-gate structure, such as the conductive layer 500 is formed on the top surface of the pre-gate structure, and the dielectric layer 600 is formed on the conductive layer 500.

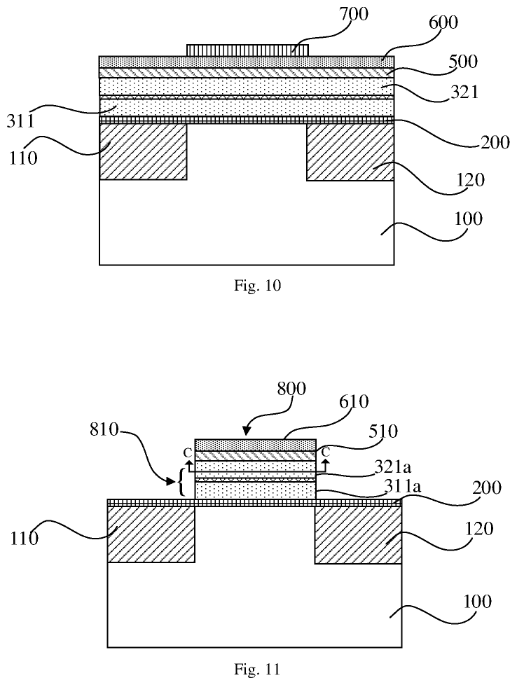

As shown in FIG. 10, in step S800, a patterned protective layer 700 is formed on a top surface of the dielectric layer 600 to cover a portion of the dielectric layer that is aligned with the region between the source region 110 and the drain region 120.

As shown in FIG. 11, in step S900, using the patterned protective layer 700 as a mask, an etching process is performed down from the dielectric layer 600 to expose the gate oxide layer 200. The protective layer 700 is etched away to form a transistor gate 800, with the gate oxide layer 200 covering the source region 110 and the drain region 120.

In the method of this embodiment, the first and second polysilicon layers are formed and separated by the first isolation oxide layer; the first and second polysilicon layers are then doped to make them conductive layers; the doped first polysilicon layer, the first isolation oxide layer, and the doped second polysilicon layer together form a pre-gate structure; the pre-gate structure is then thermally annealed so that the doped first and second polysilicon layers, while being are separated by the first isolation oxide layer, are simultaneously and separately recrystallized into the first and second conductive silicon layers, respectively; the first isolation oxide layer is thinned until an electric connection is established between the first and second conductive silicon layers; the conductive and dielectric layers are successively formed on the top surface of the thermally annealed pre-gate structure; a patterned protective layer is formed on the top surface of the dielectric layer to cover the portion of the dielectric aligned with the region between the source region and the drain region; the patterned protective layer is used as a mask for an etching process that is performed from the dielectric layer until the gate oxide layer is exposed, and subsequently, the protective layer is removed by etching to form the transistor gate, and the gate oxide layer still covers the source region and the drain region. The obtained first and second conductive silicon layers contain small-grain sized crystals, and hence the roughness of the side surfaces is reduced. The effective MOSFET gate length may be more accurate, and reliability and consistency of the device are enhanced.

The source and drain regions may be doped with ions, either in step S100 or subsequent to the formation of the gate.

The etching process in step S900 uses the patterned protective layer as a mask and etches down from the dielectric layer to expose the gate oxide layer. The etching process may include the following steps.

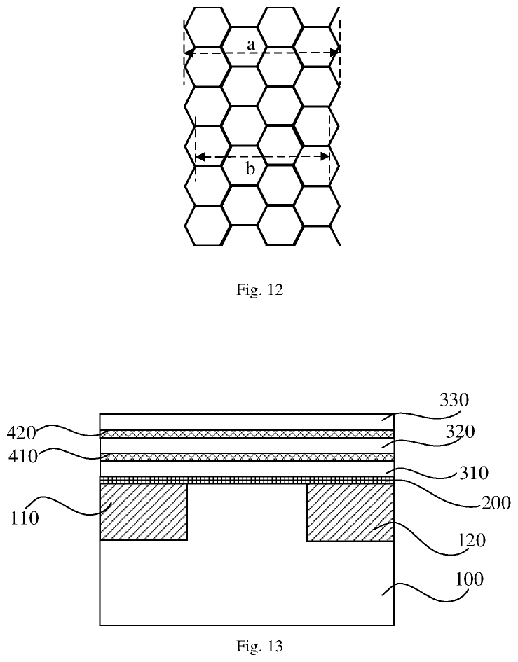

As shown in FIG. 11, a portion of the first conductive silicon layer 311 and second conductive silicon layer 321 are etched away to form a first gate conductive silicon layer 311a and a second gate conductive silicon layer 321a, respectively. The roughness of side surfaces of the first gate conductive silicon layer 311a and the second gate conductive silicon layer 321a is greater than or equal to 3% and less than or equal to 10%. FIG. 12 shows a portion of a cross-section of the second gate conductive silicon layer 321a at a plane C-C in FIG. 11. The smaller the crystals contained in the second gate conductive silicon layer 321a, the lower the roughness of its side surfaces. The roughness of the side surfaces of the second gate conductive silicon layer 321a may be expressed as (a−b)/a, where a represents the longest horizontal distance between the side surfaces of the second gate conductive silicon layer 321a, such as the distance between the outermost points of the respective side surfaces. And b represents the shortest horizontal distance between the side surfaces of the second gate conductive silicon layer 321a, such as the distance between the innermost points of the respective side surfaces. In addition, the side surfaces of the second gate conductive silicon layer 321a refer to its side surface facing the source region 110 and its side surface facing the drain region 120.

Likewise, the roughness of the side surfaces of the first gate conductive silicon layer 311a may also be expressed as (a−b)/a, where a represents the longest horizontal distance between the side surfaces of the first gate conductive silicon layer 311a, such as the distance between the outermost points of the respective side surfaces. And b represents the shortest horizontal distance between the side surfaces of the first gate conductive silicon layer 311a, such as the distance between the innermost points of the respective side surfaces. In addition, the side surfaces of the first gate conductive silicon layer 311a refer to its side surface facing the source region 110 and its side surface facing the drain region 120.

Further, the shortest distance between the innermost points on the side surfaces of the first gate conductive silicon layer 311a and the shortest distance between the innermost points on the side surfaces of the second gate conductive silicon layer 321a are defined as the effective gate length.

In the embodiments of FIGS. 2 to 8, the first and second polysilicon layers are formed and separated from each other by the first isolation oxide layer, respectively. In some embodiments of the present invention, the first polysilicon layer, the second polysilicon layer, and a third polysilicon layer may be formed and separated from each other by the first isolation oxide layer and a second isolation oxide layer, respectively. In some embodiments of the present invention, the first polysilicon layer, the second polysilicon layer, the third polysilicon layer, and a fourth polysilicon layer may be formed and separated from each other by the first isolation oxide layer, the second isolation oxide layer, and a third isolation oxide layer, respectively. And so on.

In the embodiments that the first, second and third polysilicon layers are separated from each other by the first and second isolation oxide layers, respectively, the method may further include, subsequent to step S320, the following steps.

As shown in the embodiments of FIG. 13, in step S420, a second isolation oxide layer 420 is formed on the top surface of the second polysilicon layer 320. The second isolation oxide layer 420 has a thickness greater than 0.01 nm and less than 1 nm, and preferably greater than 0.1 nm and less than 1 nm.

As shown in the embodiments of FIG. 13, in step S330, the third polysilicon layer 330 is formed on a top surface of the second isolation oxide layer 420. The second isolation oxide layer 420 separates the second polysilicon layer 320 from the third polysilicon layer 330.

In these embodiments of the present invention, in order to form the pre-gate structure, the third polysilicon layer 330 may also be doped.

As shown in FIG. 14, during the high-temperature annealing of the pre-gate structure, separated by the first isolation oxide layer 410 and the second isolation oxide layer 420, the doped first, second, and third polysilicon layers are recrystallized into a first conductive silicon layer 311, a second conductive silicon layer 321, and a third conductive silicon layer 331, respectively. The thickness of the first isolation oxide layer 410 is reduced until an electric connection is established between the first conductive silicon layer 311 and the second conductive silicon layer 321. The thickness of the second isolation oxide layer 420 is reduced until an electric connection is established between the second conductive silicon layer 321 and the third conductive silicon layer 331.

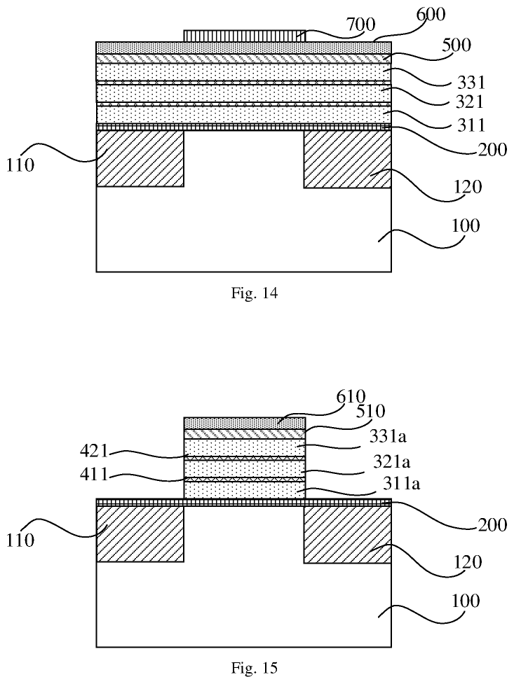

The transistor gate shown in FIG. 15, is fabricated by separating the first gate conductive silicon layer 311a from the second gate conductive silicon layer 321a by a first gate isolation oxide layer 411, and separating the second gate conductive silicon layer 321a from the third gate conductive silicon layer 331a by a second gate isolation oxide layers 421.

In the embodiments that the first, second, third, and fourth polysilicon layers are separated from each other by the respective first, second, and third isolation oxide layers, the method may further include, subsequent to step S330, the following steps.

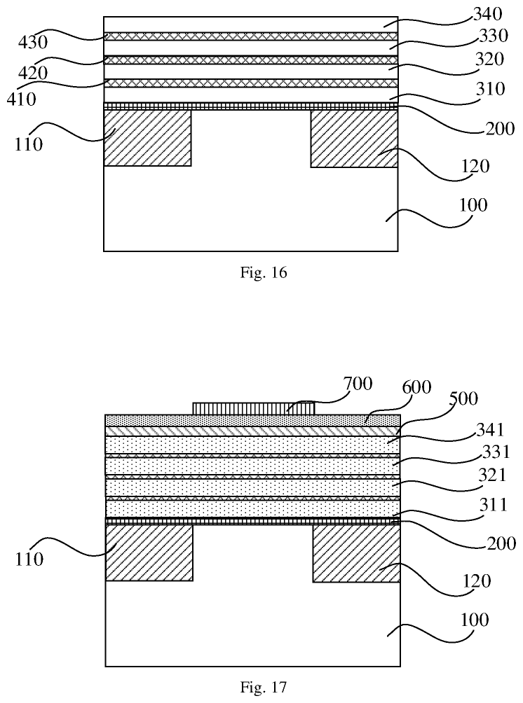

As shown in the embodiments of FIG. 16, in step S430, the third isolation oxide layer 430 is formed on a top surface of the third polysilicon layer 330, and the third isolation oxide layer 430 has a thickness that is greater than 0.01 nm and less than 1 nm, and preferably greater than 0.1 nm and less than 1 nm.

As shown in the embodiments of FIG. 16, in step S340, the fourth polysilicon layer 340 is formed on a top surface of the third isolation oxide layer 430. The third isolation oxide layer 430 is configured to separate the third polysilicon layer 330 from the fourth polysilicon layer 340.

In these embodiments, in order to form the pre-gate structure, the fourth polysilicon layer is also doped.

As shown in embodiments of FIG. 17, during the high-temperature annealing of the pre-gate structure, separated by the third isolation oxide layer 430, the doped third and fourth polysilicon layers are recrystallized into a third conductive silicon layer 331 and a fourth conductive silicon layer 341. The thickness of the third isolation oxide layer 430 is reduced until an electric connection is established between the third conductive silicon layer 331 and the fourth conductive silicon layer 341. The doped first and second polysilicon layers are recrystallized into a first conductive silicon layer 311 and a second conductive silicon layer 321. The thickness of the first isolation oxide layer 410 is reduced until an electric connection is established between the first conductive silicon layer 311 and the second conductive silicon layer 321. The thickness of the second isolation oxide layer 420 is reduced until an electric connection is established between the second conductive silicon layer 321 and the third conductive silicon layer 331.

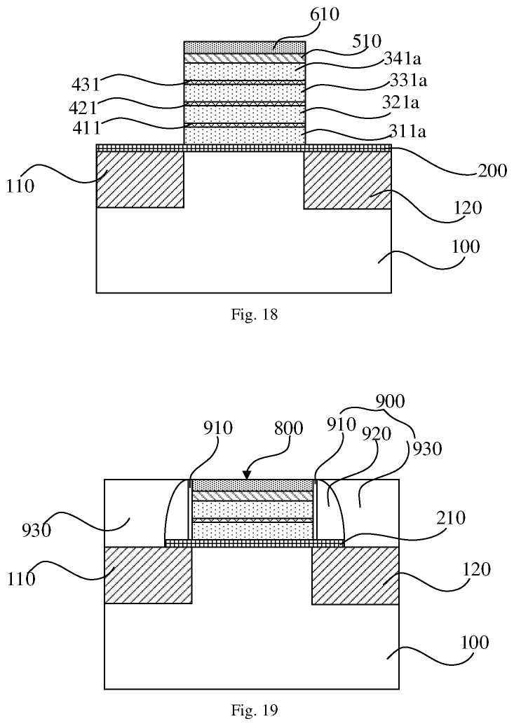

The transistor gate shown in FIG. 18, the first gate conductive silicon layer 311a, the second gate conductive silicon layer 321a, the third gate conductive silicon layer 331a, and the fourth gate conductive silicon layer 341a are separated from each other by the first gate isolation oxide layer 411, the second gate isolation oxide layer 421, and third gate isolation oxide layer 431, respectively.

After the high-temperature annealing, if the gate has a predetermined thickness, the gate may be fabricated by separating the first and second polysilicon layers with the first isolation oxide layer. The gate may be fabricated by separating the first, second, and third polysilicon layers with the first and second isolation oxide layers, respectively. The gate may also be fabricated by separating the first, second, third, and fourth polysilicon layers with the first, second, and third isolation oxide layers, respectively.

The first, second, third, or fourth polysilicon layers may have a thickness that is greater than or equal to 10 nm and less than or equal to 30 nm. The thickness of the first conductive silicon layer 311, the second conductive silicon layer 321, and the third conductive silicon layer 331 typically is generally a bit greater than that of the doped first, second, and third polysilicon layers, but generally are still in the range of 10 nm to 30 nm.

Each of the first and second polysilicon layers, may be doped with phosphorus by an ion implantation process.

The first, second, or third isolation oxide layers may be formed of a compound containing oxygen and silicon, such as silicon dioxide.

On the basis of the structure shown in the embodiments of FIG. 11, subsequent to the etching down from the dielectric layer to expose the gate oxide layer using the patterned protective layer as a mask, the method may further include the following steps.

As shown in the embodiments of FIG. 19, the gate oxide layer 200 may be etched to form a gate oxide 210 that exposes a portion of the top surface of the source region 110 and a portion of the top surface of the drain region 120. The exposed portion of the source region top surface and the exposed portion of the drain region top surface are apart from the gate oxide 210.

As shown in the embodiments of FIG. 19, lateral spacers 900 adhere to side surfaces of the transistor gate 800 and cover the exposed portion of the source region top surface, the exposed portion of the drain region top surface, and the exposed portions of the top surface of the gate oxide 210.

In the embodiment shown in FIG. 19, the lateral spacers 900 are constituted by three layers: a first spacing layer 910, a second spacing layer 920, and a third spacing layer 930. The lateral spacers 900 may be formed by corresponding steps in the transistor fabrication method.

### Embodiment 2

In the second embodiment of the present invention, a transistor structure is fabricated using the method of Embodiment 1. As shown in FIG. 19, the transistor structure includes:

a substrate 100 having a source region 110 and a drain region 120 spaced apart from each other;

a gate oxide 210 covering a portion of a top surface of the source region 110, a portion of a top surface of the drain region 120, and an exposed top surface of the substrate between the source region 110 and the drain region 120. The gate oxide 210 has a thickness that is greater than or equal to 2 nm and less than or equal to 5 nm; and

a transistor gate 800 on the gate oxide layer and aligned with the exposed potion of the top surface of the substrate 100 between the source region 110 and the drain region 120. As shown in FIG. 11, the transistor gate 800 may include a polycrystalline conductive structure 810 adhering on the gate oxide layer 200, a metal conductive layer 510 arranged on the polycrystalline conductive structure 810, and a dielectric protective layer 610 covering the metal conductive layer 510.

As shown in FIG. 11, the polycrystalline conductive structure 810 may include a first gate conductive silicon layer 311a, a second gate conductive silicon layer 321a, and a first gate isolation oxide layer 411. The first gate conductive silicon layer 311a is formed on the gate oxide layer 200 and between the source region 110 and the drain region 120. The second gate conductive silicon layer 321a is formed above and electrically connected to the first gate conductive silicon layer 311a. The first gate isolation oxide layer 411 is formed between the first and second gate conductive silicon layers to separate the first gate conductive silicon layer 311a from the second gate conductive silicon layer 321a. The first gate isolation oxide layer 411 has a thickness that is greater than 0.01 nm and less than 1 nm, and preferably greater than 0.1 num and less than 1 nm.

In the transistor gate 800 of this embodiment, the first gate isolation oxide layer 411 separates the first gate conductive silicon layer 311a from the second gate conductive silicon layer 321a. Due to the presence of the first gate isolation oxide layer 411, in a high-temperature annealing process for forming the first and second gate conductive silicon layers, the first gate conductive silicon layer 311a and the second gate conductive silicon layer 321a are restricted in the thickness direction. Thus, grain size of crystals can be restricted resulting in smaller crystals in the first and second gate conductive silicon layers. The effective MOSFET gate length can be more accurate, and the reliability and consistency of the device may be enhanced.

FIG. 12 shows a cross-section at a plane C-C of a portion of the second gate conductive silicon layer 321a in FIG. 11. The smaller the crystals contained in the second gate conductive silicon layer, the lower the roughness of its side surfaces. The roughness of the side surfaces of the second gate conductive silicon layer may be expressed as (a−b)/a, where a represents the longest horizontal distance between the side surfaces of the second gate conductive silicon layer 321a, such as the distance between the outermost points of the respective side surfaces. And b represents the shortest horizontal distance between the side surfaces of the second gate conductive silicon layer 321a, such as the distance between the innermost points of the respective side surfaces. In addition, the side surfaces of the second gate conductive silicon layer 321a refer to its side surface facing the source region 110 and its side surface facing the drain region 120. The roughness of the side surfaces of the second gate conductive silicon layer 321a may be greater than or equal to 3% and less than or equal to 10%.

Likewise, the roughness of the side surfaces of the first gate conductive silicon layer 311a may also be expressed as (a−b)/a, where a represents the longest horizontal distance between the side surfaces of the first gate conductive silicon layer 311a, such as the distance between the outermost points of the respective side surfaces. And b represents the shortest horizontal distance between the side surfaces of the first gate conductive silicon layer 311a, such as the distance between the innermost points of the respective side surfaces. In addition, the side surfaces of the first gate conductive silicon layer 311a refer to its side surface facing the source region 110 and its side surface facing the drain region 120. The roughness of the side surfaces of the first gate conductive silicon layer 311a may also be greater than or equal to 3% and less than or equal to 10%.

Further, the shortest distance between the innermost points on the side surfaces of the first gate conductive silicon layer 311a and the shortest distance between the innermost points on the side surfaces of the second gate conductive silicon layer 321a are defined as the effective gate length.

The transistor structure shown in FIG. 11 comprises the first gate conductive silicon layer 311a and second gate conductive silicon layer 321a separated from each other by the first gate isolation oxide layer 411. The transistor structure can also be constituted with the first gate conductive silicon layer 311a, the second gate conductive silicon layer 321a, and a third gate conductive silicon layer 331a, which are separated from each other by the first gate isolation oxide layer 411 and a second gate isolation oxide layer 421, respectively, as shown in FIG. 15. The transistor structure can be constituted with the first gate conductive silicon layer 311a, the second gate conductive silicon layer 321a, the third gate conductive silicon layer 331a, and a fourth gate conductive silicon layer 341a, which are separated from each other by the first gate isolation oxide layer 411, the second gate isolation oxide layer 421, and a third gate isolation oxide layer 421, respectively, as shown in FIG. 18.

As shown in the embodiments of FIG. 15, the polycrystalline conductive structure of the gate in the transistor structure that is configured with the first, second, and third gate conductive silicon layers and separated from each other by the first and second gate isolation oxide layers, further includes:

the second gate isolation oxide layer 421 which covers the second gate conductive silicon layer 321a; and

the third gate conductive silicon layer 331a covering the second gate isolation oxide layer 421 is electrically connected to the second gate conductive silicon layer 321a,

wherein the second gate isolation oxide layer 421 has a thickness that is greater than 0.01 nm and less than 1 nm, and preferably greater than 0.1 num and less than 1 nm.

As shown in the embodiments of FIG. 18, the polycrystalline conductive structure of the gate in the transistor structure that is configured with the first, second, third, and fourth gate conductive silicon layers and separated from each other by the first, second, and third gate isolation oxide layers, further includes:

the third gate isolation oxide layer 431 which covers the third gate conductive silicon layer 331a; and

the fourth gate conductive silicon layer 341a covering the third gate isolation oxide layer 431 is electrically connected to the third gate conductive silicon layer 331a,

wherein the third gate isolation oxide layer 431 has a thickness that is greater than 0.01 nm and less than 1 nm, and preferably greater than 0.1 num and less than 1 nm.

Therefore, as long as the gate has a predetermined thickness, the gate may be implemented by separating the first and second gate conductive silicon layers by the first gate isolation oxide layer. The gate may be implemented by separating the first, second, and third gate conductive silicon layers by the first and second gate isolation oxide layers. The gate may also be implemented by separating the first, second, third, and fourth gate conductive silicon layers with the first, second, and third gate isolation oxide layers.

Each of the first and second gate conductive silicon layers may have a thickness that is greater than or equal to 10 nm and less than or equal to 30 nm. In addition, each of the third and fourth gate conductive silicon layers may also have a thickness that is greater than or equal to 10 nm and less than or equal to 30 nm.

The first, second, and third isolation oxide layers may be formed of a compound containing oxygen and silicon, such as silicon dioxide.

As shown in the embodiments of FIG. 19, the transistor structure may further include lateral spacers 900 which cover side surfaces of the gate, an exposed portion of the source region top surface, an exposed portion of the drain region top surface, and the exposed portions of the top surface of the gate oxide 210.

In the embodiment shown in FIG. 19, the lateral spacers 900 are constituted by three layers: a first spacing layer 910, a second spacing layer 920, and a third spacing layer 930. The lateral spacers 900 may be formed by corresponding steps in the transistor fabrication method.

In the description of the present invention and embodiments thereof, the directional and spatial terms “top”, “bottom”, “height”, etc. are based on the directions and positions shown in the figures. They are intended merely to facilitate and simplify, but not limited to, the description of the invention. They do not indicate or imply the stated components or elements must have the specified positions, or be constructed or operated in particular orientations.

Unless defined or limited otherwise, the terms “attached”, “coupled”, “connected”, “fixed”, “fastened” or any variant thereof, should be a broad description to any connections established between two components, such as fixed, detachable, or integral connections. The connections can also include mechanical, electric, or communication connections. The connections can be directly or via an intermediate medium, through internal connection or external interaction of the elements. For those of ordinary skill in the art, the above terms can be interpreted based on their context in the embodiments of the present invention.

Unless defined or limited otherwise, when a first feature is described as being “on” or “under” a second feature, it can be in direct contact with the second feature, or through intervening features therebetween. Moreover, when a first feature is described as being “over”, “overlying” or “above” a second feature, it may either be directly above or obliquely over the second feature. The first feature may only be located higher than the second feature vertically. Similarly, when a first feature is described as being “under”, “underlying” or “beneath” a second feature, it may either be directly under or obliquely under the second feature. The first feature may only be located lower than the second feature vertically.

The above disclosure provides many different embodiments or examples for implementing different features of the present invention. Specific examples of components and arrangements are described above to simplify the present disclosure. These are, of course, merely examples and are not intended to be limiting. In addition, the present disclosure may repeat reference numerals and/or letters in the various examples. This repetition is for the purpose of simplicity and clarity and does not dictate a relationship between the various embodiments and/or configurations discussed. Further, although the disclosure provides examples of various particular processes and materials, those of ordinary skill in the art may use other processes and/or other materials.

Described above are merely a few specific embodiments of the present invention. However, the scope of the present invention is not limited to these disclosed embodiments and embraces all variations and substitutions deviated by those of ordinary skill in the art in light of the teachings disclosed herein.

What is claimed is:

1. A method for fabricating a transistor gate, comprising:
providing a substrate having a source region and a drain region spaced apart from each other;
forming a gate oxide layer on a top surface of the substrate, the gate oxide layer having a thickness that is greater than or equal to 2 nanometer (nm) and less than or equal to 5 nm;
forming a first polysilicon layer on a top surface of the gate oxide layer;
forming a first isolation oxide layer on a top surface of the first polysilicon layer, the first isolation oxide layer having a thickness that is greater than 0.1 nm and less than 1 nm;
forming a second polysilicon layer on a top surface of the first isolation oxide layer, the first isolation oxide layer separating the first polysilicon layer from the second polysilicon layer;
doping the first polysilicon layer and second polysilicon layer, wherein the doped first polysilicon layer, the first isolation oxide layer, and the doped second polysilicon layer together form a pre-gate structure;
annealing the pre-gate structure so that the doped first polysilicon layer and the doped second polysilicon layer, while being separated from each other by the first isolation oxide layer, are simultaneously and separately recrystallized to a first conductive silicon layer and a second conductive silicon layer, respectively, and the thickness of the first isolation oxide layer is reduced until an electric connection established between the first conductive silicon layer and the second conductive silicon layer;
forming a conductive layer on a top surface of the annealed pre-gate structure, and forming a dielectric layer on a top surface of the conductive layer;
forming a patterned protective layer on a top surface of the dielectric layer, the patterned protective layer covering a portion of the dielectric layer and aligned with a region between the source region and the drain region; and
etching from the dielectric layer to expose the gate oxide layer using the patterned protective layer as a mask, and removing the patterned protective layer by etching to form the transistor gate with the gate oxide layer covering the source region and the drain region.

2. The method of claim 1, further comprising:
forming a second isolation oxide layer on a top surface of the second polysilicon layer, the second isolation oxide layer having a thickness that is greater than 0.1 nm and less than 1 nm;
forming a third polysilicon layer on a top surface of the second isolation oxide layer, the second isolation oxide layer separating the second polysilicon layer from the third polysilicon layer; and
doping the third polysilicon layer, wherein the doped third polysilicon layer is recrystallized into a third conductive silicon layer during the annealing, and the thickness of the second isolation oxide layer is reduced until an electric connection established between the third conductive silicon layer and the second conductive silicon layer.

3. The method of claim 2, further comprising:
forming a third isolation oxide layer on a top surface of the third polysilicon layer, the third isolation oxide layer having a thickness that is greater than 0.1 nm and less than 1 nm;
forming a fourth polysilicon layer on a top surface of the third isolation oxide layer, the third isolation oxide layer separating the third polysilicon layer from the fourth polysilicon layer; and
doping the fourth polysilicon layer, wherein the doped fourth polysilicon layer is recrystallized to a fourth conductive silicon layer during the annealing, and the thickness of the third isolation oxide layer is reduced until an electric connection is established between the fourth conductive silicon layer and the third conductive silicon layer.

4. The method of claim 1, wherein etching from the dielectric layer to expose the gate oxide layer comprises:
etching the first conductive silicon layer and the second conductive silicon layer into a first gate conductive silicon layer and second gate conductive silicon layer, respectively, wherein a roughness of side surfaces of the first gate conductive silicon layer and the second gate conductive silicon layer is greater than or equal to 3% and less than or equal to 10%,
wherein the side surfaces of the first gate conductive silicon layer comprise a first side surface facing the source region and a second side surface facing the drain region, and the side surfaces of the second gate conductive silicon layer comprise a third side surface facing the source region and a fourth side surface facing the drain region.

5. The method of claim 1, wherein the first polysilicon layer and the second polysilicon layer have a thickness that is greater than or equal to 10 nm and less than or equal to 30 nm.

6. The method of claim 1, further comprising:
etching the gate oxide layer to form a gate oxide that exposes a portion of a top surface of the source region apart from the transistor gate and a portion of a top surface of the drain region apart from the transistor gate; and
forming lateral spacers adhering to side surfaces of the transistor gate, wherein the lateral spacers cover the exposed portion of the top surface of the source region, the exposed portion of the top surface of the drain region, and exposed portions of a top surface of the gate oxide.

7. The method of claim 1, wherein the first polysilicon layer and second polysilicon layer are doped by an ion implantation process.

8. The method of claim 1, wherein the first isolation oxide layer is formed of a material comprising silicon dioxide.

9. The method of claim 1, wherein the first conductive layer and the second conductive layer have a thickness that is greater than or equal to 10 nm and less than or equal to 30 nm.

10. A transistor structure, comprising:
a substrate having a source region and a drain region spaced apart from each other;
a gate oxide covering a portion of a top surface of the source region, a portion of a top surface of the drain region, and an exposed portion of a top surface of the substrate between the source region and the drain region, the gate oxide having a thickness that is greater than or equal to 2 nanometer (nm) and less than or equal to 5 nm; and
a transistor gate on the gate oxide and aligned with the exposed portion of the top surface of the substrate between the source region and the drain region, the transistor gate comprising a polycrystalline conductive structure adhering to the gate oxide, a metal conductive layer on the polycrystalline conductive structure, and a dielectric protective layer covering the metal conductive layer,
wherein the polycrystalline conductive structure comprises a first gate conductive silicon layer on the gate oxide between the source region and the drain region, a second gate conductive silicon layer above the first gate conductive silicon layer, the second gate conductive silicon layer electrically connected to the first gate conductive silicon layer;
wherein the transistor structure is prepared by annealing a doped first polysilicon layer and a doped second polysilicon layer so that the doped first polysilicon layer and the doped second polysilicon layer, while being separated from each other by a first gate isolation oxide layer, are simultaneously and separately recrystallized to the first gate conductive silicon layer and a second gate conductive silicon layer, respectively, and the thickness of the first gate isolation oxide layer is reduced until an electric connection established between the first gate conductive silicon layer and the second gate conductive silicon layer, and wherein the first gate isolation oxide layer comprises a thickness that is greater than 0.1 nm and less than 1 nm prior to the process of annealing.

11. The transistor structure of claim 10, wherein the polycrystalline conductive structure comprises:
a third gate conductive silicon layer covering the second gate isolation oxide layer and electrically connected to the second gate conductive silicon layer,
wherein the transistor structure is prepared by annealing the doped second polysilicon layer and a doped third polysilicon layer so that the doped second polysilicon layer and the doped third polysilicon layer, while being separated from each other by a second gate isolation oxide layer, are simultaneously and separately recrystallized to the second gate conductive silicon layer and the third gate conductive silicon layer, respectively, and the thickness of the second gate isolation oxide layer is reduced until an electric connection established between the second gate conductive silicon layer and the third gate conductive silicon layer, and wherein the second gate isolation oxide layer has a thickness that is greater than 0.1 nm and less than 1 nm prior to the process annealing.

12. The transistor structure of claim 11, wherein the polycrystalline conductive structure comprises:
a fourth gate conductive silicon layer covering the third gate isolation oxide layer and electrically connected to the third gate conductive silicon layer,
wherein the transistor structure is prepared by annealing the doped third polysilicon layer and a doped fourth polysilicon layer so that the doped third polysilicon layer and the doped fourth polysilicon layer, while being separated from each other by a third gate isolation oxide layer, are simultaneously and separately recrystallized to the third gate conductive silicon layer and the fourth gate conductive silicon layer, respectively, and the thickness of the third gate isolation oxide layer is reduced until an electric connection established between the third gate conductive silicon layer and the fourth gate conductive silicon layer, and the third gate isolation oxide layer has a thickness that is greater than 0.1 nm and less than 1 nm prior to the process of annealing.

13. The transistor structure of claim 10, wherein a roughness of side surfaces of the first gate conductive silicon layer and the second gate conductive silicon layer is greater than or equal to 3% and less than or equal to 10%.

14. The transistor structure of claim 10, wherein the first gate conductive silicon layer and the second gate conductive silicon layer have a thickness of greater than or equal to 10 nm and less than or equal to 30 nm.

15. The transistor structure of claim 10, wherein the doped first polysilicon layer and the doped second polysilicon layer have a thickness that is greater than or equal to 10 nm and less than or equal to 30 nm.

16. The transistor structure of claim 10, further comprising lateral spacers adhering to side surfaces of the transistor gate, wherein the lateral spacers cover an exposed portion of the top surface of the source region, an exposed portion of the top surface of the drain region, and exposed portions of a top surface of the gate oxide.
